(19) United States
(12) Patent Application Publication
(10) Pub. No.: US 2026/0190756 A1
(43) Pub. Date: Jul. 2, 2026

(54) Display Apparatus

(71) Applicant: LG Display Co., Ltd., Seoul (KR)

(72) Inventor: Sungbin Shim, Paju-si (KR)

(21) Appl. No.: 19/381,629

(22) Filed: Nov. 6, 2025

(30) Foreign Application Priority Data
Dec. 30, 2024 (KR) 10-2024-0200228

(51) Int. Cl. H10K 59/80; H10K 59/122; H10K 59/124; H10K 102/10

(52) U.S. Cl. CPC H10K 59/80516; H10K 59/122; H10K 59/124; H10K 59/8052; H10K 59/878; H10K 2102/103

(57) ABSTRACT

A display apparatus includes a substrate including a plurality of pixels having a plurality of subpixels, a pattern portion on the substrate and concavely toward the substrate in a non-light emission area between the plurality of subpixels, and a reflective portion on the pattern portion. Each of the plurality of subpixels includes a pixel electrode spaced apart from the reflective portion, and an auxiliary electrode connected to the pixel electrode and partially between the pixel electrode and the reflective portion. The reflective portion is partially closer to the substrate than the pixel electrode.

### CROSS-REFERENCE TO RELATED APPLICATION

This application claims the priority of Republic of Korea Patent Application No. 10-2024-0200228 filed on Dec. 30, 2024, which is hereby incorporated by reference in its entirety.

### BACKGROUND

### Field

The present disclosure relates to a display apparatus for displaying images.

### Description of Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus is reduced as some of light emitted from the light emitting element layer is not emitted to the outside due to total reflection on the interface between multiple layers inside a display panel.

### SUMMARY

An aspect of the present disclosure is directed to providing a display apparatus in which a light extraction efficiency of light emitted from a light emitting element layer may be improved.

Further, an aspect of the present disclosure is directed to providing a display apparatus in which overall power consumption may be reduced through light extraction from a non-light emission area.

Further, an aspect of the present disclosure is directed to providing a display apparatus capable of improving light efficiency.

Further, an aspect of the present disclosure is directed to providing a display apparatus capable of maximizing or at least increasing light extraction efficiency.

The problems to be solved by the examples of the present disclosure are not limited to those mentioned above, and other problems not mentioned will be apparent to one of ordinary skill in the art to which the technical spirits of the present disclosure belong from the following description.

A display apparatus comprising: a substrate including a plurality of pixels having a plurality of subpixels; a pattern portion on the substrate and concavely toward the substrate in a non-light emission area between the plurality of subpixels; and a reflective portion on the pattern portion, and each of the plurality of subpixels includes: a pixel electrode spaced apart from the reflective portion; and an auxiliary electrode connected to the pixel electrode and partially between the pixel electrode and the reflective portion, the reflective portion is partially closer to the substrate than the pixel electrode.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one or more embodiments of the present disclosure.

FIG. 2 is a schematic plan view of one pixel illustrated in FIG. 1.

FIG. 3 is a schematic cross-sectional view of the line I-I′ shown in FIG. 2.

FIG. 4 is a schematic enlarged cross-sectional view of part A shown in FIG. 3.

FIG. 5 is a schematic cross-sectional view of the line II-II′ shown in FIG. 2.

FIG. 6 is a schematic example simulating an optical reflectance of IZO (indium zinc oxide) and ITO (indium tin oxide).

FIG. 7 is a graph showing a reflectance of IZO and ITO according to wavelength.

FIG. 8 is a schematic cross-sectional view of a display apparatus according to one or more embodiments of the present disclosure.

FIG. 9 is a schematic cross-sectional view of a display apparatus according to one or more embodiments of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely one example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only’ is used. The terms of a singular form may include plural forms unless referred to the contrary.

In construing an element, the element is construed as including an error range although there is no explicit description.

In describing a position relationship, for example, when a position relation between two parts is described as ‘on’, ‘over’, ‘under’, and ‘next’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

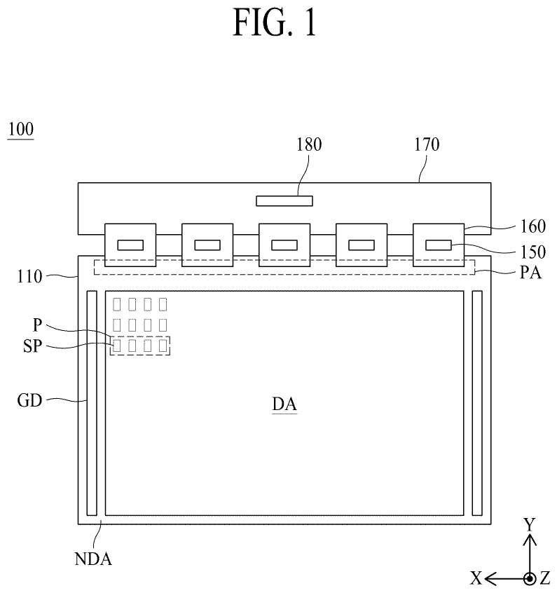

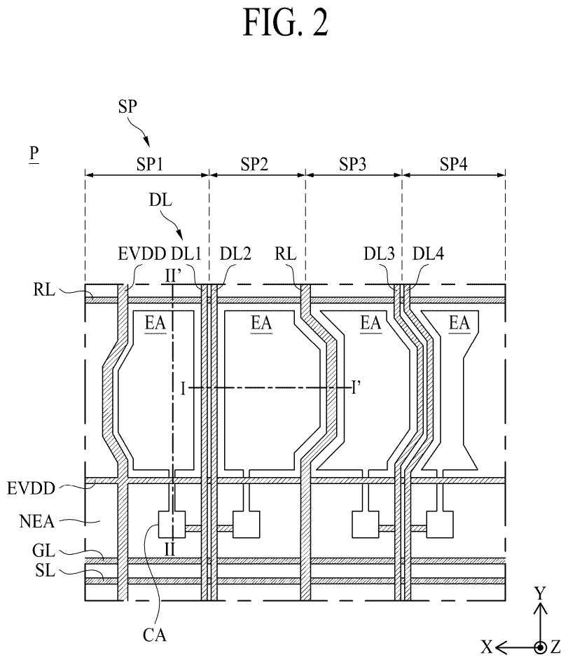

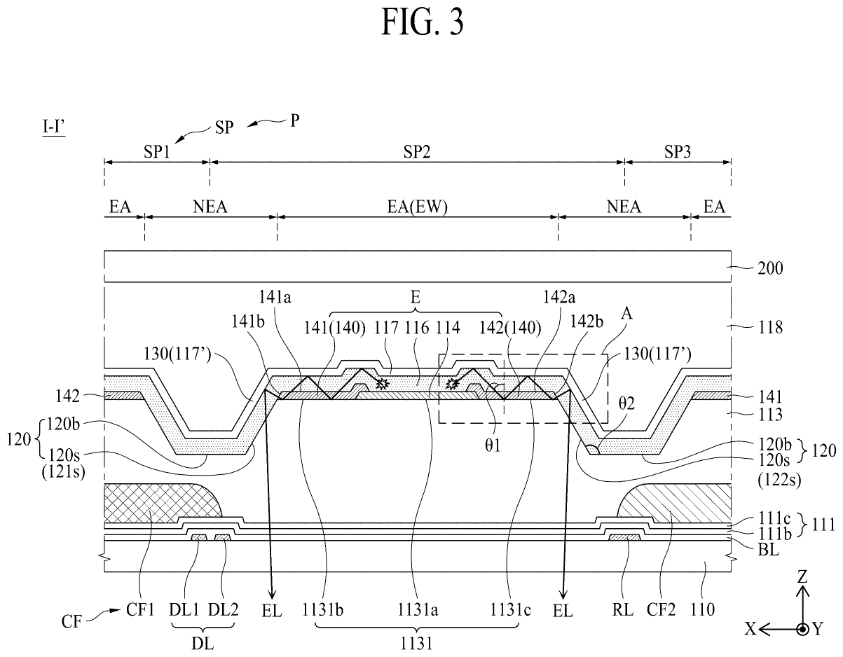

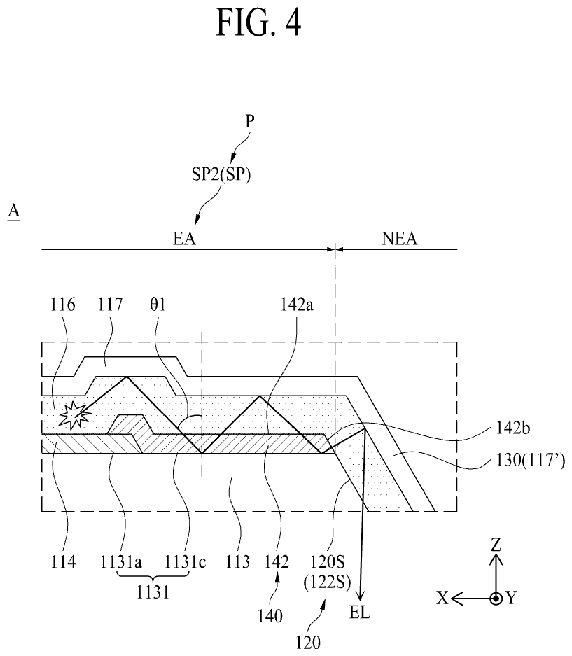

FIG. 1 is a schematic plan view of a display apparatus according to one or more embodiments of the present disclosure, FIG. 2 is a schematic plan view of one pixel illustrated in FIG. 1, FIG. 3 is a schematic cross-sectional view of the line I-I′ shown in FIG. 2, and FIG. 4 is a schematic enlarged cross-sectional view of part A shown in FIG. 3.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. The first direction (Y-axis direction) may be a direction parallel to a data line DL (shown in FIG. 2). The second direction (X-axis direction) may be a direction parallel to a gate line GL (shown in FIG. 2).

Referring to FIG. 1, the display apparatus 100 according to one or more embodiments of the present disclosure may include a display panel having a gate driver GD, a source drive integrated circuit (hereinafter, referred to as “IC”) 150, a flexible film 160, a circuit board 170, and a timing controller 180.

The display panel may include a substrate 110 and an opposite substrate 200 (shown in FIG. 3). The substrate 110 according to one example may include a plurality of pixels P having a plurality of subpixels SP.

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P. Each of the plurality of pixels P may include the plurality of sub-pixels SP.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 180. The gate driver GD may be formed on one side of the light emission area EA or in the non-light emission area NEA outside both sides of the light emission area EA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. Referring to FIG. 1, the pad area PA may be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area NDA of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

The circuit board 170 may be attached to the flexible films160. A plurality of circuits implemented as driving chips may be packaged in the circuit board 170. For example, the timing controller 180 may be packaged in the circuit board 170. The circuit board 170 may be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD, and supplies the source control signal to the source drive ICs150.

Referring to FIG. 2, the substrate 110 according to one example may include the light emission area EA and the non-light emission area NEA. Referring to FIG. 3, the display apparatus 100 may further include a pattern portion 120 formed concavely toward the substrate 110 in a non-light emission area NEA between the plurality of subpixels SP, and a reflective portion 130 disposed on the pattern portion 120.

The light emission area EA may mean an area from which light is emitted. A light emitting element layer E (shown in FIG. 3) may be disposed in the light emission area EA. According to one example, a light-emitting element layer E may include a pixel electrode 114, an auxiliary electrode 140, an organic light-emitting layer 116, and a reflective electrode 117.

The organic light-emitting layer 116 between the pixel electrode 114 and the reflective electrode 117 can emit light according to the formation of an electric field between the pixel electrode 114 and the reflective electrode 117. The organic light-emitting layer 116 between the auxiliary electrode 140 and the reflective electrode 117 can emit light according to the formation of an electric field between the auxiliary electrode 140 and the reflective electrode 117.

The auxiliary electrode 140 can be connected to the pixel electrode 114. Accordingly, the same voltage can be applied to the auxiliary electrode 140 and the pixel electrode 114. That is, the auxiliary electrode 140 and the pixel electrode 114 can function as one electrode. Accordingly, the organic light-emitting layer 116 on the auxiliary electrode 140 and the organic light-emitting layer 116 on the pixel electrode 114 can emit light together. Therefore, as shown in FIG. 3, a width EW of the light-emission area EA can be a length of the area where the pixel electrode 114 and the auxiliary electrode 140 are arranged.

Therefore, the display apparatus 100 according to one or more embodiments of the present disclosure is provided such that the auxiliary electrode 140 is connected (or electrically connected) to the pixel electrode 114, so that the width EW (or size) of the light-emission area EA can be increased, thereby improving light efficiency.

As shown in FIG. 3, some of the light emitted from the organic light-emitting layer 116 may be totally reflected between an interface between the planarization layer 113 and the auxiliary electrode 140 and the reflective electrode 117 (or a lower surface of the reflective electrode 117) to form an optical path toward an adjacent subpixel (or a non-emitting subpixel).

Since the pattern portion 120 is formed concavely toward the substrate 110 and the reflective portion 130 is disposed on the pattern portion 120, the reflective portion 130 may be partially disposed closer to the substrate 110 than the pixel electrode 114. Further, in this embodiment, the reflective portion 130 may be partially disposed closer to the substrate 110 than the auxiliary electrode 140. According to one or more embodiments of the present disclosure, the display apparatus 100 can reflect light directed toward an adjacent subpixel toward a emitting subpixel SP (or an emission area EA) by arranging the reflective portion 130 between subpixels SP, and light reflected by the reflective portion 130 can be emitted toward the non-light emission area NEA or the light emission area EA. Accordingly, the display apparatus 100 according to one or more embodiments of the present disclosure can improve the light efficiency of a light-emitting subpixel by extracting light directed toward an adjacent subpixel by the reflective portion 130. In addition, the display apparatus 100 according to one or more embodiments of the present disclosure can prevent color mixing due to the reflective portion 130 disposed between the subpixels SP.

As a result, the display apparatus 100 according to one or more embodiments of the present disclosure can improve light efficiency while preventing color mixing with adjacent subpixels (or adjacent non-emitting subpixels) through the reflective portion 130 on the pattern portion 120 of the non-light emission area NEA.

Referring back to FIG. 2, the light emission area EA according to one example may include gate lines, data lines, pixel driving power lines, and a plurality of pixels P. Each of the plurality of pixels P may include a plurality of subpixels SP that may be defined by the gate lines and the data lines.

At least four subpixels, which are provided to emit different colors and disposed to be adjacent to one another, among the plurality of subpixels SP may constitute one pixel P (or unit pixel). One pixel P may include, but is not limited to, a red subpixel, a white subpixel, a blue subpixel and a green subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layers disposed in each of the plurality of sub-pixels SP may emit white light in common. Since the light emitting layer of each of the plurality of sub-pixels SP emits white light in common, each of the red sub-pixel, the green sub-pixel, and the blue sub-pixel may include a color filter CF (or wavelength conversion member CF) that converts the white light to the respective colored light. In this case, the white sub-pixel may not comprise a color filter.

In the display apparatus 100 according to one or more embodiments of the present disclosure, the area with the red color filter CF1 (shown in FIG. 3) may be a red sub-pixel or a first sub-pixel SP1, the area without the color filter may be a white sub-pixel or a second sub-pixel SP2, the area with the blue color filter CF2 (shown in FIG. 3) may be a blue sub-pixel or a third sub-pixel SP3, and the area with the green color filter may be a green sub-pixel or a fourth sub-pixel SP4.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in a second direction (X-axis direction).

The plurality of subpixels SP may include a first subpixel SP1, a second subpixel SP2, a third subpixel SP3 and a fourth subpixel SP4 arranged adjacent to each other in the second direction (X-axis direction). For example, the first subpixel SP1 may be a red subpixel, the second subpixel SP2 may be a white subpixel, the third subpixel SP3 may be a blue subpixel and the fourth subpixel SP4 may be a green subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area CA. The light emission area EA may be disposed at one side (or an upper side) of a subpixel area, and the circuit area CA may be disposed at the other side (or a lower side) of the subpixel area. For example, the circuit area CA may be disposed at one side (or the lower side) of the light emission area EA. The light emission area EA of each of the first to fourth sub-pixels SP1 to SP4 may have different sizes (or areas), but are not limited thereto.

The first to fourth subpixels SP1 to SP4 may be disposed to be adjacent to one another along the second direction (X-axis direction). For example, two data lines DL extended long along the first direction (Y-axis direction) may be disposed in parallel with each other between the first subpixel SP1 and the second subpixel SP2 and between the third subpixel SP3 and the fourth subpixel SP4. A pixel power line EVDD (or branch wiring of the pixel power line) extended along the second direction (X-axis direction) may be disposed between the light emission area EA and the circuit area CA of each of the first to fourth subpixels SP1 to SP4. The gate line GL and a sensing line SL may be disposed below the circuit area CA.

The pixel power line EVDD (shown in FIG. 2) extended along the first direction (Y-axis direction) may be disposed at one side of the first subpixel SP1 or the fourth subpixel SP4. A reference line RL extended long along the first direction (Y-axis direction) may be disposed between the second subpixel SP2 and the third subpixel SP3. The reference line RL may be used as a sensing line for sensing a change of characteristics of a driving thin film transistor and/or a change of characteristics of the light emitting element layer, which is disposed in the circuit area, from the outside in a sensing driving mode of the pixel P.

In one example, the data lines DL are for supplying data signals to each of the plurality of the sub-pixels SP to drive each of the plurality of the sub-pixels SP. For example, the data lines DL may include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

In the display apparatus 100 according to one or more embodiments of the present disclosure, a lines may be disposed not to overlap the light emission area EA. For example, the second data line DL2 may be arranged such that it does not overlap the light emission area EA, as shown in FIG. 3. Thus, in the display apparatus 100 according to one or more embodiments of the present disclosure, the lines do not overlap (or is not interfered with) light emitted from the light emission area EA, thus a decrease in light extraction efficiency may be prevented.

The first data line DL1, the third data line DL3, and the fourth data line DL4, like the second data line DL2, may be disposed in the non-light emission area NEA of the corresponding sub-pixel so as not to be overlapped the light emission area EA of the corresponding sub-pixel in the third direction (Z-axis direction). Thus, in the display apparatus 100 according to one or more embodiments of the present disclosure, the data lines DL1, DL2, DL3, DL4 may have a structural feature that do not overlap the light emission area EA but overlap the non-light emission area NEA (or pattern portion 120).

On the other hand, each of the pixel power line EVDD and the reference line RL may be disposed in the non-light emission area NEA so as not to obscure (or interfere with) light emitted from the light emission area EA, such as the data lines described above.

Referring to FIG. 3, in the display apparatus 100 according to one or more embodiments of the present disclosure, the pixel electrode 114 may be arranged spaced apart from the reflective portion 130. This is because the pixel electrode 114 is arranged at a center portion of an upper surface 1131 included in the planarization layer 113. In contrast, the auxiliary electrode 140 is connected to the pixel electrode 114 and may be arranged at an edge of the pixel electrode 114. For example, the auxiliary electrode 140 may be partially arranged between the pixel electrode 114 and the reflective portion 130. Accordingly, the auxiliary electrode 140 may be arranged closer to the reflective portion 130 than the pixel electrode 114.

As shown in FIG. 3, the auxiliary electrode 140 may be placed on the upper surface 1131 of the planarization layer 113. Accordingly, the upper surface 1131 of the planarization layer 113 may be in contact with each of the pixel electrode 114 and the auxiliary electrode 140. The reflective portion 130 may be placed on the pattern portion 120.

Referring to FIG. 3, the pattern portion 120 may be formed on the planarization layer 113 disposed on the substrate 110. According to one example, the pattern portion 120 may be formed concavely in the non-light emission area NEA between the plurality of subpixels SP by patterning and removing the planarization layer 113 between the plurality of subpixels SP. After the pattern portion 120 is formed concavely, the organic light-emitting layer 116 and the reflective electrode 117 may be sequentially deposited on the entire surface in a subsequent process. Therefore, as shown in FIG. 3, the organic light-emitting layer 116 and the reflective electrode 117 can be formed concavely in the non-light-emission area NEA along a profile of the pattern portion 120. Here, the reflective electrode 117 formed concavely in the non-light emission area NEA can be the reflective portion 130. Since the reflective portion 130 is a part of the reflective electrode 117 arranged in the non-light emission area NEA, it can be indicated by the drawing symbol 117′.

The pattern portion 120 according to one example may be provided to surround the light emission area EA in the form of a slit or a trench. A width of the pattern portion 120 may be formed to be reduced from the reflective portion 130 toward the substrate 110. Therefore, the pattern portion 120 may be expressed as terms such as a groove, a slit, and a trench. As shown in FIG. 3, the pattern portion 120 may include an inclined surface 120s connected to an upper surface 1131 of the planarization layer 113, and a bottom surface 120b connected to the inclined surface 120s and provided flat.

The bottom surface 120b of the pattern portion 120 according to one example is the surface formed closest to the substrate 110 in the pattern portion 120, and may be positioned closer to the substrate 110 than the upper surface 1131 (or pixel electrode 114) of the planarization layer 113 in the light-emission area EA.

The inclined surface 120s of the pattern portion 120 may be arranged between the bottom surface 120b and the light-emission area EA. Therefore, the inclined surface 120s of the pattern portion 120 may be arranged adjacent to the light-emission area EA of each of the plurality of subpixels SP. As shown in FIG. 3, the inclined surface 120s may be connected to the bottom surface 120b. The inclined surface 120s may form a predetermined angle with the bottom surface 120b. For example, an angle (a second angle θ2) formed by the inclined surface 120s and the bottom surface 120b may be an obtuse angle. Accordingly, a width of the pattern portion 120 may be designed to gradually decrease in a direction (or third direction (Z-axis direction)) toward the substrate 110 from the opposing substrate 200 (or the reflective portion 130). Since the inclined surface 120s and the bottom surface 120b form an obtuse angle, the organic light-emitting layer 116 and the reflective portion 130 formed in the subsequent process may be formed concavely along the profile of the pattern portion 120.

At least a portion of the reflective portion 130 arranged obliquely on the pattern portion 120 may be arranged adjacent to the light-emission area EA. Accordingly, in the display apparatus 100 according to one or more embodiments of the present disclosure, light extraction may also be performed in the non-light emission area NEA around the light-emission area EA, so that the overall light efficiency may be improved. Therefore, the display apparatus 100 according to one or more embodiments of the present disclosure can have the same light-emitting efficiency or can have improved light-emitting efficiency even at low power compared to a general display apparatus without a pattern portion 120 and a reflective portion 130 on the pattern portion 120, so that the overall power consumption can be reduced.

In addition, since the display apparatus 100 according to one or more embodiments of the present disclosure can emit light from the organic light-emitting element layer E even at low power, the lifespan of the organic light-emitting element layer E (or the organic light-emitting layer 116) can be improved.

According to one example, the pattern portion 120 may be placed between subpixels SP that emit different colors. Accordingly, a reflective portion 130 that is arranged obliquely on the pattern portion 120 may also be placed between subpixels SP that emit different colors, and as a result, the reflective portion 130 may prevent light of different colors from being emitted to adjacent subpixels SP. Therefore, the display apparatus 100 according to one or more embodiments of the present disclosure can prevent color mixing (or color distortion) between subpixels SP that emit different colors, thereby improving color purity.

According to one example, the reflective portion 130 may be formed concavely along the profile of the pattern portion 120 formed concavely in the non-light emission area NEA. Accordingly, the reflective portion 130 may be formed slantedly in the non-light emission area NEA. The reflective portion 130 is formed of a material capable of reflecting light, so that light emitted from the light emission area EA and directed toward an adjacent subpixel SP may be reflected toward the light emission area EA that emits light. As illustrated in FIG. 3, the reflective portion 130 is arranged adjacent to the light-emission area EA and is arranged obliquely on the pattern portion 120, so it can be expressed as a side reflective portion or an oblique reflective portion.

Referring to FIG. 3, in the display apparatus 100 according to one or more embodiments of the present disclosure, a reflected light EL reflected by the reflective portion 130 and emitted to an outside of the substrate 110 may refer to light emitted from the organic light-emitting layer 116, guided by a light waveguide (or waveguide) through total reflection between an interface between the auxiliary electrode 140 and the planarization layer 113 and the reflective electrode 117, and then reflected by the reflective portion 130 and emitted to the substrate 110. The reflected light EL may be emitted from the non-light emission area NEA or the light emission area EA.

In the display apparatus 100 according to one or more embodiments of the present disclosure, a refractive index of the auxiliary electrode 140 may be greater than a refractive index of the pixel electrode 114. This is to increase the total reflection (or internal total reflection) of light emitted from the organic light-emitting layer 116 and incident toward the auxiliary electrode 140.

Meanwhile, a refractive index of the planarization layer 113 may be smaller than a refractive index of the pixel electrode 114. This is due to a difference in materials forming each of the planarization layer 113 and the pixel electrode 114. For example, the planarization layer 113 may be formed of an organic material (e.g., PI or PAC), and the pixel electrode 114 may be formed of a transparent conductive material (e.g., ITO (indium tin oxide)). Accordingly, the refractive index of the planarization layer 113 may be smaller than the refractive index of the pixel electrode 114.

The auxiliary electrode 140 according to one example may be formed of IZO (indium zinc oxide). Accordingly, a refractive index of the auxiliary electrode 140 may be greater than a refractive index of the pixel electrode 114. For example, the refractive index of the pixel electrode 114 formed of ITO may be about 1.9. In contrast, the refractive index of the auxiliary electrode 140 formed of IZO may be about 2.1.

As described above, since the pixel electrode 114 and the auxiliary electrode 140 are provided on the planarization layer 113, if the refractive index of the auxiliary electrode 140 is greater than the refractive index of the pixel electrode 114, a difference in the refractive indices between the auxiliary electrode 140 and the planarization layer 113 may be greater than a difference in the refractive indices between the pixel electrode 114 and the planarization layer 113. Accordingly, light emitted from the organic light-emitting layer 116 and incident toward the auxiliary electrode 140 may have increased total reflection (or internal total reflection) at an interface between the auxiliary electrode 140 and the planarization layer 113. For example, in the display apparatus 100 according to one or more embodiments of the present disclosure, a difference in refractive index between the auxiliary electrode 140 and the planarization layer 113 may be 0.5 or more.

As shown in FIG. 3, light emitted from the organic light-emitting layer 116 on the pixel electrode 114 and incident at a first angle θ1 toward the auxiliary electrode 140 is first totally reflected (or totally internally reflected) at an interface between the auxiliary electrode 140 and the planarization layer 113 due to a difference in refractive index between the auxiliary electrode 140 and the planarization layer 113, and may be secondarily reflected by the reflective electrode 117. Light (or wave-guided light) reflected several times by the interface between the auxiliary electrode 140 and the planarization layer 113 and the reflective electrode 117 can reach the reflective portion 130. The light reaching the reflective portion 130 can be reflected by the reflective portion 130 and emitted to the substrate 110. Accordingly, since the display apparatus 100 according to one or more embodiments of the present disclosure has a difference in refractive index between the auxiliary electrode 140 and the planarization layer 113 of 0.5 or more, light incident on the auxiliary electrode 140 can be reflected several times by the interface between the auxiliary electrode 140 and the planarization layer 113 and the reflective electrode 117, thus improving light efficiency.

Referring to FIG. 4, some of the light emitted from the organic light-emitting layer 116 on the pixel electrode 114 may be incident at a first angle θ1 with respect to a direction perpendicular to an upper surface 142a of the auxiliary electrode 140 (or a second auxiliary electrode 142). Here, the first angle θ1 may be 48.4°or more and less than 90°. If light emitted from the organic light-emitting layer 116 is incident on the auxiliary electrode 140 at an angle of less than 48.4°, it may not be totally reflected at the interface between the auxiliary electrode 140 and the planarization layer 113 but may be incident on the planarization layer 113 and emitted toward an adjacent subpixel. In this case, color mixing may occur. In addition, since the organic light-emitting layer 116 on the pixel electrode 114 emits light above the pixel electrode 114, it cannot be incident at a 90°angle onto the auxiliary electrode 140.

Meanwhile, if the difference in refractive index between the auxiliary electrode 140 and the planarization layer 113 is less than 0.5, even if light is incident at the first angle θ1 toward the auxiliary electrode 140, it may not be totally reflected at the interface between the auxiliary electrode 140 and the planarization layer 113. In this case, since the light is emitted to the adjacent subpixel SP through the planarization layer 113, color mixing may occur. As another example, if the difference in refractive index between the auxiliary electrode 140 and the planarization layer 113 is less than 0.5, the minimum total reflection angle at the interface between the auxiliary electrode 140 and the planarization layer 113 may be 63.6°. In this case, the total reflection (or internal total reflection) between the interface between the auxiliary electrode 140 and the planarization layer 113 and the reflective electrode 117 may be reduced, so that the light extraction efficiency may be minimal or at least reduced.

Therefore, in the display apparatus 100 according to one or more embodiments of the present disclosure, the first angle θ1 at which light is emitted from the organic light-emitting layer 116 and incident on the auxiliary electrode 140 is 48.4° or more and less than 90°, and the difference in refractive index between the auxiliary electrode 140 and the planarization layer 113 is 0.5 or more, so that color mixing with adjacent subpixels SP can be prevented, while light extraction efficiency can be maximized or at least increased through multiple total reflections (or internal total reflections) at the interface between the auxiliary electrode 140 and the planarization layer 113.

In the display apparatus 100 according to one or more embodiments of the present disclosure, the auxiliary electrode 140 may be formed later than the pixel electrode 114. For example, the auxiliary electrode 140 may be formed to cover an edge of the pixel electrode 114 after the pixel electrode 114 is formed. Accordingly, as shown in FIG. 3, the display apparatus 100 according to one or more embodiments of the present disclosure may have a structural feature in which an auxiliary electrode 140 is connected to a pixel electrode 114, and an edge of the pixel electrode 114 is positioned between the auxiliary electrode 140 and a planarization layer 113.

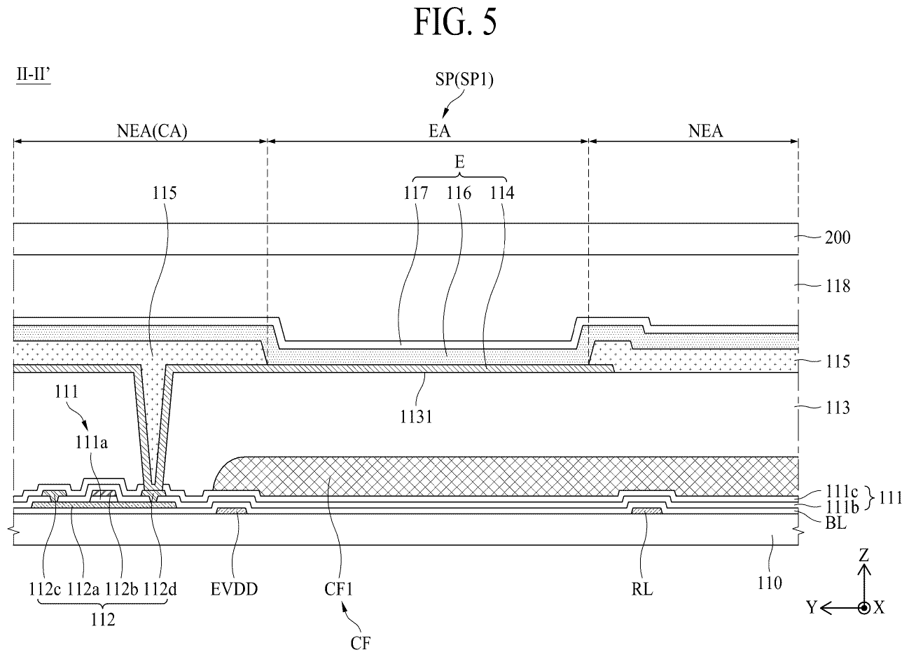

Hereinafter, the structure of each of the plurality of subpixels SP will be specifically described with reference to FIG. 5.

FIG. 5 is a schematic cross-sectional view of the line II-II′ shown in FIG. 2.

Referring to FIG. 5, the display apparatus 100 according to one or more embodiments of the present disclosure can include a buffer layer BL, a plurality of inorganic films 111, a thin film transistor 112, a color filter CF, a planarization layer 113, a pixel electrode 114, a bank 115, an organic light emitting layer 116, a reflective electrode 117, and an encapsulation layer 118.

Each of the subpixels SP according to one or more embodiments may include the plurality of inorganic films 111 provided on an upper surface of the buffer layer BL, including a gate insulating layer 111a, an interlayer insulating layer 111b, and a passivation layer 111c.

Also, each of the subpixels SP may include a color filter CF provided on the plurality of inorganic films 111, a planarization layer 113 provided on the color filter CF. The pixel electrode 114 may be placed on the planarization layer 113.

Each of the subpixels SP may further include a bank 115 covering one edge of the pixel electrode 114, an organic light-emitting layer 116 on the pixel electrode 114 and the bank 115, and a reflective electrode 117 on the organic light-emitting layer 116. The encapsulation layer 118 may be placed on the reflective electrode 117.

The thin film transistor 112 for driving of subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, the interlayer insulating layer 111b, and the passivation layer 111c. The pixel electrode 114, the organic light emitting layer 116 and the reflective electrode 117 may be included in a light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 3, in the circuit area CA and the subpixel SP.

The source electrode 112c may be electrically connected to the source area of the active layer 112a through a source contact hole provided in the interlayer insulating layer overlapped with the source area of the active layer 112a.

The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

Additionally, the thin film transistor provided in the pixel area may have a characteristic in which the threshold voltage is shifted by light. To prevent this, the display panel or the substrate 110 may further include a light-shielding layer (not shown) provided under the active layer 112a of at least one of the thin film transistor 112, a first switching thin film transistor, and a second switching thin film transistor.

The light-shielding layer is provided between the substrate 110 and the active layer 112a to block light incident on the active layer 112a through the substrate 110, thereby minimizing or at least reducing changes in the threshold voltage of the transistor caused by external light. In addition, the light shielding layer may be provided between the substrate 110 and the active layer 112a to prevent the thin film transistor from being visible to the user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

The color filter CF may be placed on the passivation layer 111c. For example, the color filter CF may be placed between the plurality of inorganic films 111 and the planarization layer 113. The color filter CF may include a red color filter CF1 arranged in the red subpixel SP1, a blue color filter CF2 arranged in the blue subpixel SP3, and a green color filter (not shown) arranged in the green subpixel SP4. Since the white subpixel SP2 is provided to emit white light, it may not include the color filter.

The planarization layer 113 may be provided on the substrate 110 to cover the passivation layer 111c and the color filter CF. When the passivation layer 111c is omitted, the planarization layer 113 can be provided on the substrate 110 to cover the circuit area. The planarization layer 113 may be formed in the entire circuit area CA in which the thin film transistor 112 is disposed and the entire light emission area EA. In addition, the planarization layer 113 may be formed in the other non-display area NDA except a pad area PA of the non-display area NDA and the entire display area DA. For example, the planarization layer 113 may include an extension portion (or an enlarged portion) extended or enlarged from the display area DA to the other non-display area NDA except the pad area PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

Since the upper surface 1131 of the planarization layer 113 is provided flat, the pixel electrode 114 and the auxiliary electrode 140 on the planarization layer 113 can also be provided flat, and the organic light-emitting layer 116 and the reflective electrode 117 formed thereon can also be provided in a flat form. Since the pixel electrode 114, the auxiliary electrode 140, the organic light-emitting layer 116, and the reflective electrode 117, i.e., the organic light-emitting element layer E, are provided flatly in the light-emission area EA, a thicknesses of the pixel electrode 114, the auxiliary electrode 140, the organic light-emitting layer 116, and the reflective electrode 117 can be formed uniformly within the light-emission area EA. Accordingly, the organic light-emitting layer 116 can emit light uniformly without deviation within the light-emission area EA.

Meanwhile, the pattern portion 120 (shown in FIG. 3) can be formed by patterning and removing a portion of the planarization layer 113. According to one example, the pattern portion 120 can be formed on the planarization layer 113 through a photo process using a mask having an opening, and a pattern (or etching) or ashing process after the photo process. After the pattern portion 120 is formed, the pixel electrode 114 and the auxiliary electrode 140 are sequentially patterned and formed for each subpixel SP on the planarization layer 113, and then the organic light-emitting layer 116 and the reflective electrode 117 can be formed on the entire surface.

The pixel electrode 114 may be formed on the planarization layer 113. As shown in FIG. 5, the pixel electrode 114 can be connected to a drain electrode or source electrode of the thin film transistor through a contact hole penetrating the planarization layer 113, and the passivation layer 111c. An edge portions on both sides of the pixel electrode 114 may be covered by the bank 115. Since FIG. 5 is a cross-sectional view in the first direction (Y-axis direction), the bank 115 may be provided to cover each of an upper edge and a lower edge of the pixel electrode 114 based on a plane (e.g., FIG. 2). In contrast, the bank 115 may not be placed between a plurality of sub-pixels SP that are equipped to emit different colors. For example, the bank 115 may not be placed between the first sub-pixel SP1 and the second sub-pixel SP2 that are equipped to emit different colors. Accordingly, the display apparatus 100 according to one or more embodiments of the present disclosure may be provided with a structure (or bankless structure) in which the bank 115 is not arranged between the plurality of sub-pixels SP arranged in the second direction (X-axis direction) (e.g., between the first sub-pixel SP1 and the second sub-pixel SP2).

The pixel electrode 114 may be made of at least one of a transparent metal material or a semi-transmissive metal material.

Because the display apparatus 100 according to one or more embodiments of the present disclosure is configured as the bottom emission type, the pixel electrode 114 may be formed of a transparent conductive material (or TCO), such as indium tin oxide (ITO) capable of transmitting light. The pixel electrode 114 may be a first electrode or an anode electrode.

After the pixel electrode 114 is formed, the auxiliary electrode 140 may be formed. As shown in FIG. 3, the auxiliary electrode 140 may be provided to cover the edge of the pixel electrode 114. According to one example, the auxiliary electrode 140 may be provided with a material having a higher refractive index than the pixel electrode 114. This is to increase the total reflection (or total internal reflection) of light emitted from the organic light-emitting layer 116 on the pixel electrode 114 and incident on the auxiliary electrode 140. In addition, the auxiliary electrode 140 may be formed of a material that is easier to etch than the pixel electrode 114 made of ITO. Since the pixel electrode 114 is formed before the auxiliary electrode 140, if the pixel electrode 114 is damaged during an etching process of the auxiliary electrode 140, a light efficiency is reduced.

The display apparatus 100 according to one or more embodiments of the present disclosure has the auxiliary electrode 140 made of IZO, so that it has a higher refractive index than the pixel electrode 114 and can be etched more easily than the pixel electrode 114. Accordingly, in the display apparatus 100 according to one or more embodiments of the present disclosure, since the auxiliary electrode 140 made of IZO is partially disposed between the pixel electrode 114 and the reflective portion 130, light extraction efficiency can be maximized or at least increased due to an increase in total reflection within the substrate 110, and reliability can also be improved because the pixel electrode 114 made of ITO is not damaged.

The bank 115 may be an area, which does not emit light, and can be placed adjacent to the light emission area EA of each of the plurality of sub-pixels SP. For example, the bank 115 may be disposed in the non-light emission area NEA (or the non-light emission area NEA located above and below the light emission area EA of FIG. 2). The bank 115 may be formed to cover a portion where an edge of each of the pixel electrode 114 and the auxiliary electrode 140. Accordingly, the bank 115 may prevent the pixel electrode 114 and the reflective electrode 117 from coming into contact at the edge of the pixel electrode 114. Additionally, the bank 115 may prevent the auxiliary electrode 140 and the reflective electrode 117 from coming into contact at an edge of the auxiliary electrode 140. An exposed portion of the pixel electrode 114 that is not covered by the bank 115 and an exposed portion of the auxiliary electrode 140 that is not covered by the bank 115 may be included in the light-emitting portion (or light-emission area EA).

Although FIG. 5 depicts that only the pixel electrode 114 is covered by the bank 115, FIG. 5 is a cross-sectional view of the light-emission area EA (or pixel electrode 114) on the plane of FIG. 2 cut in the first direction (Y-axis direction). A cross-sectional view of the auxiliary electrode 140 cut in the first direction (Y-axis direction) on a plane may be replaced with the auxiliary electrode 140 being placed instead of the pixel electrode 114 in FIG. 5. Accordingly, the bank 115 may be provided to cover the edges of each of the pixel electrode 114 and the auxiliary electrode 140.

Meanwhile, when a process of baking the bank 115 is performed, the pixel electrode 114 made of ITO can be crystallized. For example, when a material forming the bank 115 is baked, the amorphous pixel electrode 114 can be crystallized into a crystalline pixel electrode 114. Therefore, the crystalline pixel electrode 114 can be not damaged in a process of etching the auxiliary electrode 140 on the pixel electrode 114, This is because IZO is easier etched by a fluorine-based etchant than ITO. Therefore, in the display apparatus 100 according to one or more embodiments of the present disclosure, the auxiliary electrode 140 covering the edge of the pixel electrode 114 can be formed without damaging the pixel electrode 114.

After the bank 115 is formed, an organic light emitting layer 116 may be formed to cover the pixel electrode 114, the auxiliary electrode 140, and the bank 115. Thus, the bank 115 may be provided between the pixel electrode 114 and the organic light emitting layer 116, and the auxiliary electrode 140 and the organic light emitting layer 116. The bank 115 can be expressed in terms of a pixel definition films. The bank 115 according to one example may comprise organic material and/or inorganic material.

The organic light emitting layer 116 may be formed on the pixel electrode 114, the auxiliary electrode 140, and the bank 115. According to one example, the organic light emitting layer 116 may be disposed in the light emission area EA and the non-light emission area NEA.

The organic light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 may emit light. That is, the organic light-emitting layer 116 between the pixel electrode 114 and the reflective electrode 117 can emit light according to the formation of an electric field between the pixel electrode 114 and the reflective electrode 117.

In addition, since the organic light-emitting layer 116 is provided between the auxiliary electrode 140 and the reflective electrode 117, when voltage is applied to each of the auxiliary electrode 140 and the reflective electrode 117, an electric field is formed between the auxiliary electrode 140 and the reflective electrode 117, so that the organic light-emitting layer 116 can emit light. That is, the organic light-emitting layer 116 between the auxiliary electrode 140 and the reflective electrode 117 can emit light according to the formation of an electric field between the auxiliary electrode 140 and the reflective electrode 117.

Since the auxiliary electrode 140 is connected to the pixel electrode 114, the same voltage can be applied to the auxiliary electrode 140 and the pixel electrode 114 at the same time. Accordingly, the organic light-emitting layer 116 on each of the pixel electrode 114 and the auxiliary electrode 140 can emit light at the same time.

The organic light emitting layer 116 may be formed of a common layer provided on a plurality of subpixels SP and the bank 115. The organic light emitting layer 116 according to one or more embodiments may be provided to emit white light. The organic light emitting layer 116 may include a plurality of stacks which emit lights of different colors. For example, the organic light emitting layer 116 may include a first stack, a second stack, and a charge generating layer CGL provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to one or more embodiments of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

That is, in the display apparatus 100 according to one or more embodiments of the present disclosure, the organic light-emitting layer 116 (or organic light-emitting element layer E) may be formed in a tandem structure.

The reflective electrode 117 may be formed on the organic light-emitting layer 116. The reflective electrode 117 may be arranged in the light-emission area EA and the non-light emission area NEA. The reflective electrode 117, according to one example, may include a metal material. The reflective electrode 117 may reflect light emitted from the organic light-emitting layer 116 in the plurality of subpixels SP toward the lower surface of the substrate 110. Therefore, the display apparatus 100 according to one or more embodiments of the present disclosure may be implemented as a bottom emission display apparatus.

The display apparatus 100 according to one or more embodiments of the present disclosure is a bottom emission type and has to reflect light emitted from the light emitting layer 116 toward the substrate 110, and thus the reflective electrode 117 may be made of a metal material having high reflectance. According to one example, the reflective electrode 117 may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode, and an opposing electrode.

Meanwhile, in the display apparatus 100 according to one or more embodiments of the present disclosure, the reflective portion 130 may be a part of the reflective electrode 117. Accordingly, the reflective portion 130 may reflect light directed toward an adjacent subpixel SP toward the light-emission area EA of an emitting subpixel SP. The reflective portion 130 may mean a reflective electrode 117′that overlaps the pattern portion 120. According to one example, the reflective portion 130 may mean a reflective electrode 117′ that is inclined while overlapping the pattern portion 120.

The encapsulation layer 118 is formed on the reflective electrode 117. The encapsulation layer 118 serves to prevent oxygen or moisture from penetrating into the organic light-emitting layer 116 and the reflective electrode 117. The encapsulation layer 118 may be provided with a plurality of layers including at least one inorganic film and at least one organic film. The encapsulation layer 118 may further contain an absorbent material for absorbing moisture or oxygen in order to enhance the moisture-prevention effect. For example, the absorbent material may be a getter. The encapsulation layer 118 may be arranged not only in the light-emission area EA but also in the non-light emission area NEA. The encapsulation layer 118 may be arranged between the reflective electrode 117 and the opposing substrate 200.

Referring again to FIG. 3, in the display apparatus 100 according to one or more embodiments of the present disclosure, the upper surface 1131 of the planarization layer 113 may include a first surface 1131a, a second surface 1131b, and a third surface 1131c. The first surface 1131a, the second surface 1131b, and the third surface 1131c may also be referred to “the first surface section”, “the second surface section”, and “the third surface section”, respectively.

The first surface 1131a may be a surface in contact with the pixel electrode 114. The second surface 1131b and the third surface 1131c may be connected to the first surface 1131a and may be arranged on both sides based on the first surface 1131a. For example, with reference to FIG. 3, the second surface 1131b may be arranged on a left side of the first surface 1131a, and the third surface 1131c may be arranged on a right side of the first surface 1131a. The first surface 1131a, the second surface 1131b, and the third surface 1131c may be provided flat.

According to one example, an auxiliary electrode 140 may include a first auxiliary electrode 141 and a second auxiliary electrode 142.

The first auxiliary electrode 141 may partially overlap with the first surface 1131a and the second surface 1131b. For example, a part of the first auxiliary electrode 141 may overlap with the first surface 1131a in the third direction (Z-axis direction) on the pixel electrode 114. A remainder of the first auxiliary electrode 141 may overlap with the second surface 1131b in the third direction (Z-axis direction). As shown in FIG. 3, the remainder of the first auxiliary electrode 141 may be in contact with the second surface 1131b. The first auxiliary electrode 141 may include an upper surface 141a and an end 141b connected to the upper surface 141a.

The second auxiliary electrode 142 may be arranged spaced apart from the first auxiliary electrode 141. For example, the second auxiliary electrode 142 may be arranged spaced apart from the first auxiliary electrode 141 with respect to the pixel electrode 114. The second auxiliary electrode 142 may partially overlap with the first surface 1131a and the third surface 1131c. For example, a part of the second auxiliary electrode 142 may overlap with the first surface 1131a in the third direction (Z-axis direction) on the pixel electrode 114. A remainder of the second auxiliary electrode 142 may overlap with the third surface 1131c in the third direction (Z-axis direction). As shown in FIG. 3, the remainder of the second auxiliary electrode 142 may be in contact with the third surface 1131c. The second auxiliary electrode 142 may include an upper surface 142a and an end 142b connected to the upper surface 142a.

As illustrated in FIG. 3, in the display apparatus 100 according to one or more embodiments of the present disclosure, the first auxiliary electrode 141 and the second auxiliary electrode 142 are electrically connected and arranged on both sides of the pixel electrode 114, so that a width EW (or size) of the light-emission area EA can be increased, thereby improving light efficiency.

Meanwhile, in the display apparatus 100 according to one or more embodiments of the present disclosure, the first auxiliary electrode 141 and the second auxiliary electrode 142 may be disposed only on the upper surface of the planarization layer 113. Accordingly, some of the light emitted from the organic light-emitting layer 116 on the pixel electrode 114 may be reflected by an interface between the first auxiliary electrode 141 and the second surface 1131b and the reflective electrode 117, thereby forming a light path to the reflective portion 130 (e.g., the reflective portion 130 on a left with reference to FIG. 2). In addition, another portion of the light emitted from the organic light-emitting layer 116 on the pixel electrode 114 may be reflected by an interface between the second auxiliary electrode 142 and the third surface 1131c and the reflective electrode 117 to form an optical path to the reflective portion 130 (e.g., the reflective portion 130 on a right with reference to FIG. 2). Accordingly, the light reaching the reflective portion 130 may be reflected by the reflective portion 130 and emitted to an outside of the substrate 110.

Referring to FIG. 3, the inclined surface 120s of the pattern portion 120 may include a first inclined surface 121s and a second inclined surface 122s. The first inclined surface 121s may be connected to the second surface 1131b of the planarization layer 113. The second inclined surface 122s may be connected to the third surface 1131c of the planarization layer 113. According to one example, the first inclined surface 121s may be provided in a symmetrical form with respect to the pixel electrode 114 and the second inclined surface 122s.

As described above, in the display apparatus 100 according to one or more embodiments of the present disclosure, the first auxiliary electrode 141 and the second auxiliary electrode 142 may be disposed only on the upper surface 1131 of the planarization layer 113. Therefore, as shown in FIG. 3, the display apparatus 100 according to one or more embodiments of the present disclosure may have a structural feature in which the end 141b of the first auxiliary electrode 141 is provided to coincide with a joint between the first inclined surface 121s and the upper surface 1131, and the end 142b of the second auxiliary electrode 142 is provided to coincide with a joint between the second inclined surface 122s and the upper surface 1131. In other words, the first auxiliary electrode 141 is provided to terminate at the joint between the first inclined surface 121s and the upper surface 1131, and the second auxiliary electrode 142 is provided to terminate at the joint between the second inclined surface 122s and the upper surface 1131.

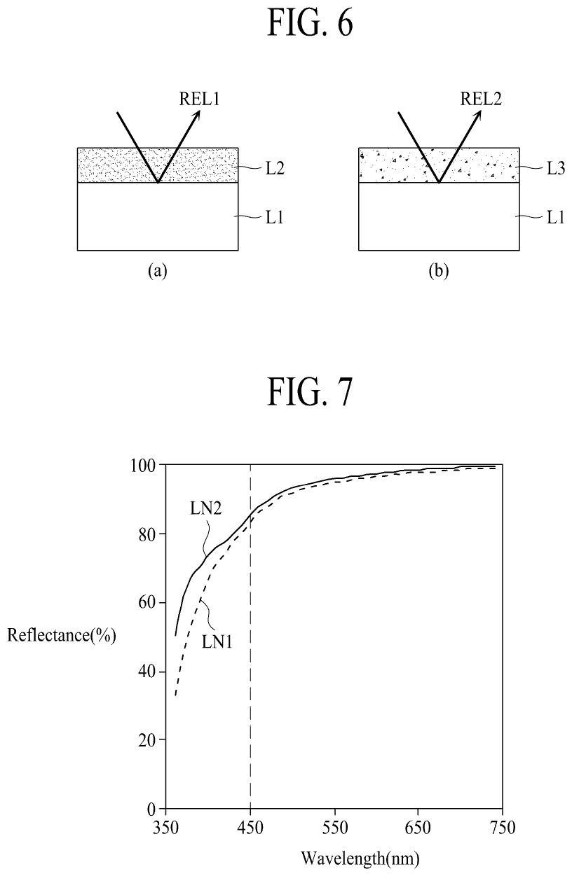

Hereinafter, with reference to FIGS. 6 and 7, a transmittance of a pixel electrode 114 made of ITO and a transmittance of an auxiliary electrode 140 made of IZO of the display apparatus 100 according to one or more embodiments of the present disclosure will be described from the perspective of reflectance.

FIG. 6 is a schematic example simulating an optical reflectance of IZO and ITO, and FIG. is a graph showing a reflectance of IZO and ITO according to wavelength.

Referring to FIG. 6, diagram (a) is an exemplary diagram schematically illustrating first reflected light REL1 that is incident on a second layer L2 and then reflected by a first layer L1 and emitted, in a state where the second layer L2 is laminated on the first layer L1. Here, the first layer L1 may be an electrode made of Ag or an alloy of Ag and ITO. The second layer L2 may be an electrode made of IZO (or an auxiliary electrode 140 made of IZO).

Referring to FIG. 6, diagram (b) is one example diagram schematically illustrating second reflected light REL2 that is incident on a third layer L3 and then reflected by the first layer L1 and emitted, in a state where the third layer L3 is laminated on the first layer L1. Here, the first layer L1 may be an electrode made of Ag, or an alloy of Ag and ITO. The third layer L3 may be an electrode made of ITO (or a pixel electrode 114 made of ITO). The inventor of the display apparatus 100 according to one or more embodiments of the present disclosure simulated the light reflectance for the electrode having the laminated structure of (a) and (b), and the result is as shown in FIG. 7.

Referring to FIG. 7, a horizontal axis represents wavelength, and a vertical axis represents reflectance (or light reflectance). LN1 is a graph showing light intensity according to wavelength of FIG. 6(a). That is, LN1 is a graph showing reflectance according to wavelength of an electrode made of IZO (or the auxiliary electrode 140 made of IZO). LN2 is a graph showing light intensity according to wavelength of FIG. 6(b). That is, LN2 is a graph showing reflectance according to wavelength of an electrode made of ITO (or the pixel electrode 114 made of ITO).

As shown in FIG. 7, it can be seen that LN2 has a higher reflectivity in the short wavelength range of 450 nm or less than LN 1. For example, at a blue wavelength of about 400 nm, LN 1 has a reflectivity of about 65%, while LN 2 has a reflectivity of about 72%, which is higher than LN 1. Since the simulations of (a) and (b) of FIG. 6 are both in which light is reflected by the first layer L1, a high reflectivity may mean that the transmittance of the layer on the first layer L1 is high. Accordingly, it can be seen that a transmittance of an electrode made of ITO (or the pixel electrode 114 made of ITO) is higher than a transmittance of an electrode made of IZO (or the auxiliary electrode 140 made of IZO) in the blue wavelength range (or short wavelength range) below 450 nm.

The display apparatus 100 according to one or more embodiments of the present disclosure may have the pixel electrode 114 disposed in a central portion of the light-emission area EA, and an auxiliary electrode 140 disposed at an edge of the pixel electrode 114. As described above, in the short wavelength region (for example, in the blue wavelength region of 450 nm or less), a transmittance of the pixel electrode 114 is greater than a transmittance of the auxiliary electrode 140, so that light corresponding to the short wavelength region among the light emitted from the light-emitting region EA of the blue subpixel SP3 can pass through the pixel electrode 114 with high transmittance and be emitted to the outside (or outer side) of the substrate 110 through the blue color filter CF2. Accordingly, the display apparatus 100 according to one or more embodiments of the present disclosure may have a light transmittance of the pixel electrode 114 greater than a light transmittance of the auxiliary electrode 140 in a short wavelength range (e.g., 450 nm or less), thereby improving a light efficiency in the blue subpixel SP3.

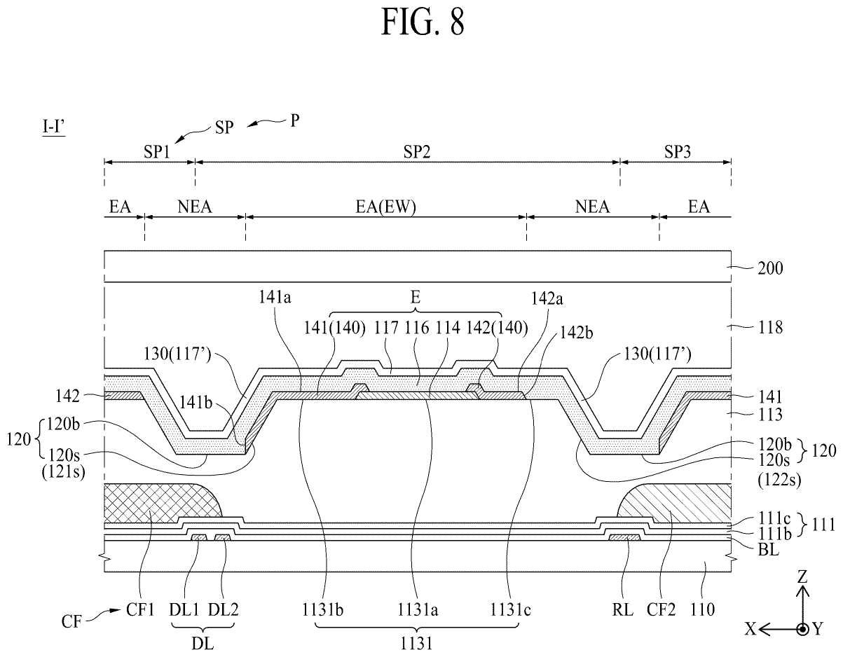

FIG. 8 is a schematic cross-sectional view of a display apparatus according to one or more embodiments of the present disclosure.

Referring to FIG. 8, the display apparatus 100 according to one or more embodiments of the present disclosure is the same as the display apparatus according to FIG. 1 described above, except that the structures of the first auxiliary electrode 141 and the second auxiliary electrode 142 are changed. Therefore, the same drawing reference numerals are given to the same configurations, and only different configurations will be described below.

In the case of the display apparatus according to FIG. 1, the first auxiliary electrode 141 and the second auxiliary electrode 142 can be placed only on the upper surface of the planarization layer 113. Accordingly, in the case of the display apparatus according to FIG. 1, some of the light emitted from the organic light-emitting layer 116 on the pixel electrode 114 may be reflected by an interface between the first auxiliary electrode 141 and the second surface 1131b and the reflective electrode 117 to reach the reflective portion 130, and then be reflected by the reflective portion 130 to be emitted to the outside of the substrate 110. And, in the case of the display apparatus according to FIG. 1, another portion of the light emitted from the organic light-emitting layer 116 on the pixel electrode 114 may be reflected by the interface between the second auxiliary electrode 142 and the third surface 1131c and the reflective electrode 117 to reach the reflective portion 130, and then be reflected by the reflective portion 130 to be emitted to the outside of the substrate 110. Meanwhile, in the case of the display apparatus according to FIG. 1, it may have a structural feature in which the end 141b of the first auxiliary electrode 141 is provided to coincide with the joint between the first inclined surface 121s and the upper surface of the planarization layer 113, and the end 142b of the second auxiliary electrode 142 is provided to coincide with the joint between the second inclined surface 122s and the upper surface of the planarization layer 113. Accordingly, in the display apparatus according to FIG. 1, the first auxiliary electrode 141 may be provided in a symmetrical form with the second auxiliary electrode 142 with respect to the pixel electrode 114.

In contrast, in the case of the display apparatus according to FIG. 8, the first auxiliary electrode 141 may be provided so as to extend to the first inclined surface 121s and cover the first inclined surface 121s, and the second auxiliary electrode 142 may be provided so as not to cover the second inclined surface 122s. This case may correspond to a case where the exposure process is performed by deflecting (or shifting) an opening of a mask for patterning the auxiliary electrode 140 to a left with respect to the pixel electrode 114. Accordingly, in the case of the display apparatus according to FIG. 8, a length of the first auxiliary electrode 141 may be provided to be longer than a length of the second auxiliary electrode 142.

Therefore, in the case of the display apparatus according to FIG. 8, some of the light emitted from the organic light-emitting layer 116 on the pixel electrode 114 may be reflected by an interface between the first auxiliary electrode 141 and the second surface 1131b and the reflective electrode 117, and may also be reflected by an interface between the first auxiliary electrode 141 and the first inclined surface 121s and the reflective electrode 117. That is, in the case of the display apparatus according to FIG. 8, a total reflection (or internal total reflection) at the first auxiliary electrode 141 may be further increased compared to the case of the display apparatus according to FIG. 1. In contrast, another portion of the light emitted from the organic light-emitting layer 116 on the pixel electrode 114 may be reflected only by the reflective electrode 117 and the interface between the second auxiliary electrode 142 and the third surface 1131c, which has a shorter length than the interface between the first auxiliary electrode 141 and the second surface 1131b. Therefore, in the case of the display apparatus according to FIG. 8, a total reflection (or internal total reflection) at the second auxiliary electrode 142 may be reduced compared to the case of the display apparatus according to FIG. 1.

As a result, the display apparatus 100 according to FIG. 8 may have a reduced total reflection (or internal total reflection) at the second auxiliary electrode 142, but an increased total reflection (or internal total reflection) at the first auxiliary electrode 141. Accordingly, the display apparatus 100 according to FIG. 8 may have the same or similar light extraction efficiency as the display apparatus according to FIG. 1. However, the display apparatus 100 according to FIG. 8 has a structural difference from the display apparatus according to FIG. 1 in that the first auxiliary electrode 141 and the second auxiliary electrode 142 are provided in an asymmetrical form with respect to the pixel electrode 114.

Meanwhile, the display apparatus 100 according to FIG. 8 may be provided with a shorter length of the second auxiliary electrode 142 and a longer length of the first auxiliary electrode 141 compared to the display apparatus according to FIG. 1. Accordingly, the display apparatus 100 according to FIG. 8 may be provided with a width EW that is the same as the light-emission area EA of the display apparatus according to FIG. 1.

Additionally, the display apparatus 100 according to FIG. 8 may have a structural feature in which a length of the second auxiliary electrode 142 is shorter and a length of the first auxiliary electrode 141 is longer than that of the display apparatus according to FIG. 1, so that the end 142b of the second auxiliary electrode 142 is arranged on the third surface 1131c of the planarization layer 113, and the end 141b of the first auxiliary electrode 141 is arranged on a boundary portion (or the bottom surface 120b) between the first inclined surface 121s and the bottom surface 120b.

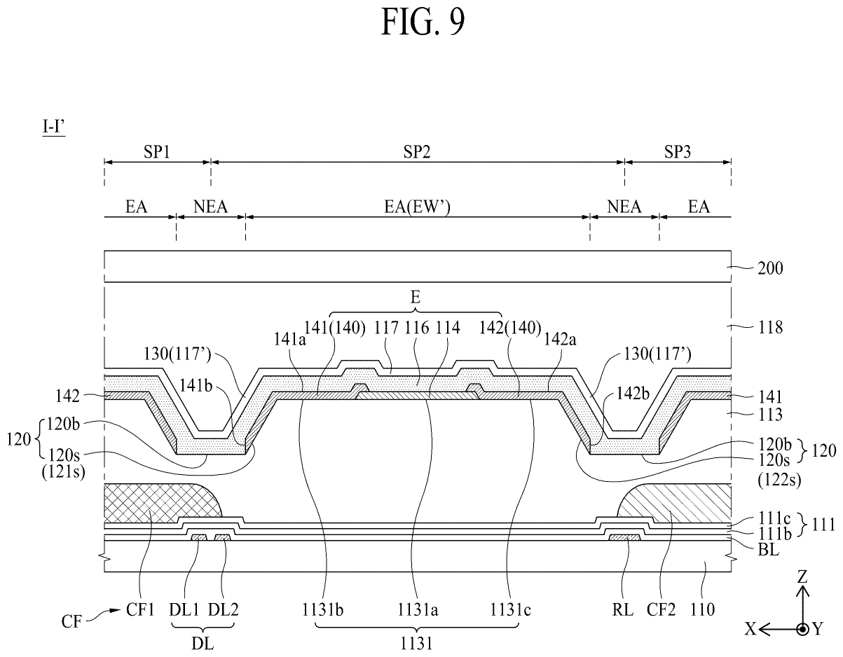

FIG. 9 is a schematic cross-sectional view of a display apparatus according to one or more embodiments of the present disclosure.

Referring to FIG. 9, the display apparatus 100 according to one or more embodiments of the present disclosure is the same as the display apparatus according to FIG. 1 described above, except that the structures of the first auxiliary electrode 141 and the second auxiliary electrode 142 are changed. Therefore, the same drawing reference numerals are given to the same configurations, and only different configurations will be described below.

In the case of the display apparatus according to FIG. 1, the first auxiliary electrode 141 and the second auxiliary electrode 142 can be placed only on the upper surface of the planarization layer 113. Accordingly, in the case of the display apparatus according to FIG. 1, some of the light emitted from the organic light-emitting layer 116 on the pixel electrode 114 may be reflected by an interface between the first auxiliary electrode 141 and the second surface 1131b and the reflective electrode 117 to reach the reflective portion 130, and then be reflected by the reflective portion 130 to be emitted to the outside of the substrate 110. And, in the case of the display apparatus according to FIG. 1, another portion of the light emitted from the organic light-emitting layer 116 on the pixel electrode 114 may be reflected by the interface between the second auxiliary electrode 142 and the third surface 1131c and the reflective electrode 117 to reach the reflective portion 130, and then be reflected by the reflective portion 130 to be emitted to the outside of the substrate 110. Meanwhile, in the case of the display apparatus according to FIG. 1, it may have a structural feature in which the end 141b of the first auxiliary electrode 141 is provided to coincide with the first inclined surface 121s, and the end 142b of the second auxiliary electrode 142 is provided to coincide with the second inclined surface 122s. Accordingly, in the display apparatus according to FIG. 1, the first auxiliary electrode 141 may be provided in a symmetrical form with the second auxiliary electrode 142 with respect to the pixel electrode 114.

In contrast, in the case of the display apparatus according to FIG. 9, the first auxiliary electrode 141 may be provided to extend to the first inclined surface 121s to cover the first inclined surface 121s, and the second auxiliary electrode 142 may be provided to extend to the second inclined surface 122s to cover the second inclined surface 122s. This case may correspond to a case where an opening of a mask for patterning the auxiliary electrode 140 of the display apparatus according to FIG. 9 is provided to be larger than an opening of a mask for patterning the auxiliary electrode 140 of the display apparatus according to FIG. 1. Accordingly, in the case of the display apparatus according to FIG. 9, a length of each of the first auxiliary electrode 141 and the second auxiliary electrode 142 may be provided to be longer than a length of each of the first auxiliary electrode 141 and the second auxiliary electrode 142 of the display apparatus according to FIG. 1.

Therefore, in the case of the display apparatus according to FIG. 9, some of the light emitted from the organic light-emitting layer 116 on the pixel electrode 114 may be reflected by an interface between the first auxiliary electrode 141 and the second surface 1131b and the reflective electrode 117, and may also be reflected by an interface between the first auxiliary electrode 141 and the first inclined surface 121s and the reflective electrode 117. That is, in the case of the display apparatus according to FIG. 9, a total reflection (or internal total reflection) at the first auxiliary electrode 141 can be further increased compared to a case of the display apparatus according to FIG. 1.

In addition, another portion of the light emitted from the organic light-emitting layer 116 on the pixel electrode 114 may be reflected by an interface between the second auxiliary electrode 142 and the third surface 1131c and the reflective electrode 117, and may also be reflected by an interface between the first auxiliary electrode 141 and the second inclined surface 122s and the reflective electrode 117. That is, in the case of the display apparatus according to FIG. 9, a total reflection (or internal total reflection) at the second auxiliary electrode 142 can be further increased compared to the case of the display apparatus according to FIG. 1. As a result, in the display apparatus 100 according to FIG. 9, both a total reflection (or internal total reflection) at the first auxiliary electrode 141 and a total reflection (or internal total reflection) at the second auxiliary electrode 142 can be increased.

The display apparatus 100 according to FIG. 9 is similar to the display apparatus according to FIG. 1 in that the first auxiliary electrode 141 is provided symmetrically with the second auxiliary electrode 142 with respect to the pixel electrode 114, but has a structural difference from the display apparatus according to FIG. 1 in that a length of each of the first auxiliary electrode 141 and the second auxiliary electrode 142 are provided longer than that of the corresponding auxiliary electrode in the display apparatus according to FIG. 1.

Meanwhile, the display apparatus 100 according to FIG. 9 may be provided with a longer length of each of the first auxiliary electrode 141 and the second auxiliary electrode 142 compared to the display apparatus according to FIG. 1, thereby having a wider width EW′ than the width EW of the light-emission area EA of the display apparatus according to FIG. 1. Accordingly, the display apparatus 100 according to FIG. 9 may have a greater ratio of light emitted by being emitted from the organic light-emitting layer 116 than light emitted by being totally reflected (or totally internally reflected) at an interface between the auxiliary electrode 140 and the planarization layer 113 than the display apparatus according to FIG. 1. In addition, the display apparatus 100 according to FIG. 9 has each of the first auxiliary electrode 141 and the second auxiliary electrode 142 longer than the display apparatus according to FIG. 1, thereby satisfying the needs of users who want a wider light-emission area EA width than the display apparatus according to FIG. 1.

As a result, the display apparatus 100 according to one or more embodiments of the present disclosure can easily change a length of each of the first auxiliary electrode 141 and the second auxiliary electrode 142 simply by adjusting a size of a mask opening for forming the first auxiliary electrode 141 and the second auxiliary electrode 142, so that a degree of freedom for a width (or size) of the light-emission area EA can be improved. Therefore, the display apparatus 100 according to one or more embodiments of the present disclosure can flexibly respond to a design of the width (or size) of the light-emission area EA desired by the user while satisfying the user's needs.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this disclosure shall be construed to be included within the scope of the claims of this disclosure.

The display apparatus according to one or more embodiments of the present disclosure is provided to have the reflective portion disposed on the pattern portion that is formed to be concave between the plurality of sub-pixels, so that light directed at the adjacent sub-pixels may be reflected from the reflective portion, thereby improving light extraction efficiency.

Since the display apparatus according to one or more embodiments of the present disclosure may have light extraction even in the non-light emission area through the reflective portion, it may have the same light extraction efficiency or even better light extraction efficiency with lower power compared to a display apparatus without the reflective portion, thereby reducing overall power consumption.

The display apparatus according to one or more embodiments of the present disclosure is provided to include an auxiliary electrode connected to the pixel electrode, so that a width (or size) of a light-emission area can be increased, thereby improving light efficiency.

The display apparatus according to one or more embodiments of the present disclosure is provided to include an auxiliary electrode having a higher refractive index than the pixel electrode, so that light extraction efficiency can be maximized or at least increased due to an increase in total reflection within the substrate.

The effects to be obtained from the present disclosure are not limited to those mentioned above, and other effects not mentioned will be apparent to one of ordinary skill in the art from the description.

What is claimed is:

1. A display apparatus, comprising:
a substrate including a plurality of pixels having a plurality of subpixels;
a pattern portion on the substrate and concavely toward the substrate in a non-light emission area between the plurality of subpixels; and
a reflective portion on the pattern portion, and
wherein each of the plurality of subpixels includes:
a pixel electrode spaced apart from the reflective portion; and
an auxiliary electrode connected to the pixel electrode and partially between the pixel electrode and the reflective portion,
wherein the reflective portion is partially closer to the substrate than the pixel electrode.

2. The display apparatus of claim 1, wherein a refractive index of the auxiliary electrode is greater than a refractive index of the pixel electrode.

3. The display apparatus of claim 1, wherein the pixel electrode includes indium tin oxide (ITO), and the auxiliary electrode includes indium zinc oxide (IZO).

4. The display apparatus of claim 1, wherein a transmittance of the pixel electrode is greater than a transmittance of the auxiliary electrode in a short wavelength region of 450 nm or less than 450 nm.

5. The display apparatus of claim 1, further comprising:
a planarization layer between the substrate and the pixel electrode, and
wherein the planarization layer includes an upper surface in contact with each of the pixel electrode and the auxiliary electrode.

6. The display apparatus of claim 5, wherein an edge of the pixel electrode is between the auxiliary electrode and the planarization layer.

7. The display apparatus of claim 5, wherein a refractive index of the auxiliary electrode is greater than a refractive index of the planarization layer.

8. The display apparatus of claim 7, wherein a difference between a refractive index of the auxiliary electrode and a refractive index of the planarization layer is 0.5 or more than 0.5.

9. The display apparatus of claim 5, wherein the pattern portion is on the planarization layer, and the pattern portion includes:
an inclined surface connected to an upper surface of the planarization layer; and
a bottom surface connected to the inclined surface and closer to the substrate than the upper surface of the planarization layer.

10. The display apparatus of claim 9, wherein the inclined surface forms an obtuse angle with the bottom surface.

11. The display apparatus of claim 1, further comprising:
a bank covering two opposite edges in a first direction of each of the pixel electrode and the auxiliary electrode.

12. The display apparatus of claim 11, wherein the plurality of subpixels include a first subpixel and a second subpixel that are configured to emit different colors,
wherein the first subpixel and the second subpixel are adjacent to each other in a second direction perpendicular to the first direction, and
wherein the bank is not between the first subpixel and the second subpixel in the second direction.

13. The display apparatus of claim 5, wherein each of the plurality of subpixels further includes:
an organic light-emitting layer on the pixel electrode and the auxiliary electrode; and
a reflective electrode on the organic light-emitting layer, and
wherein the reflective portion is a part of the reflective electrode that is over the pattern portion.

14. The display apparatus of claim 13, wherein the organic light-emitting layer between the auxiliary electrode and the reflective electrode emits light caused by an electric field between the auxiliary electrode and the reflective electrode.

15. The display apparatus of claim 13, wherein a portion of light emitted from the organic light-emitting layer on the pixel electrode is incident at a first angle with respect to a direction perpendicular to an upper surface of the auxiliary electrode,
wherein the light incident at the first angle is totally reflected at an interface between the auxiliary electrode and the planarization layer, and
wherein the first angle is at least 48.4°and less than 90°.

16. The display apparatus of claim 9, wherein an upper surface of the planarization layer includes:
a first surface section contacting the pixel electrode; and
a second surface section and a third surface section connected to the first surface section and on both sides of the first surface section, and
wherein the auxiliary electrode includes:
a first auxiliary electrode partially overlapping the first surface section and the second surface section; and
a second auxiliary electrode spaced apart from the first auxiliary electrode and partially overlapping the first surface section and the third surface section.

17. The display apparatus of claim 16, wherein the first auxiliary electrode and the second auxiliary electrode are on an upper surface of the planarization layer.

18. The display apparatus of claim 16, wherein the inclined surface comprises:
a first inclined surface connected to the second surface section; and
a second inclined surface connected to the third surface section, and
wherein an end of the first auxiliary electrode coincides with a joint between the first inclined surface and the second surface section, and
wherein an end of the second auxiliary electrode coincides with a joint between the second inclined surface and the third surface section.

19. The display apparatus of claim 16, wherein the inclined surface comprises:
a first inclined surface connected to the second surface section; and
a second inclined surface connected to the third surface section, and
wherein the first auxiliary electrode extends to the first inclined surface and covers the first inclined surface, and
wherein the second auxiliary electrode does not cover the second inclined surface.

20. The display apparatus of claim 16, wherein the inclined surface comprises:
a first inclined surface connected to the second surface section; and
a second inclined surface connected to the third surface section, and
wherein the first auxiliary electrode extends to the first inclined surface and covers the first inclined surface, and
wherein the second auxiliary electrode extends to the second inclined surface and covers the second inclined surface.
